(19) United States
(12) Patent Application Publication
(10) Pub. No.: US 2026/0324236 A1
(43) Pub. Date: Oct. 15, 2026

(54) DISPLAY PANEL AND DISPLAY DEVICE

(71) Applicants: HEFEI BOE JOINT TECHNOLOGY CO., LTD., Hefei (CN); BOE TECHNOLOGY GROUP CO., LTD., Beijing (CN); BEIJING BOE TECHNOLOGY DEVELOPMENT CO., LTD., Beijing (CN)

(72) Inventors: Luke DING, Beijing (CN); Yongqian LI, Beijing (CN)

(21) Appl. No.: 18/996,282

(22) PCT Filed: Aug. 26, 2024
(86) PCT No.: PCT/CN2024/114542

§ 371 Date: Jan. 17, 2025

(30) Foreign Application Priority Data
Sep. 28, 2023 (CN) 202311285063.1

(51) Int. Cl. H10K 59/35; H10K 59/121; H10K 59/122; H10K 59/123; H10K 59/126; H10K 59/131; H10K 59/80; H10K 102/00

(52) U.S. Cl. CPC H10K 59/35; H10K 59/1213; H10K 59/1216; H10K 59/122; H10K 59/123; H10K 59/126; H10K 59/1315; H10K 59/80522; H10K 2102/3031

(57) ABSTRACT

A display panel and a display device are provided. The display panel includes a plurality of pixels (PX), each of the plurality of pixels (PX) includes a plurality of sub-pixels (SP), in a same pixel (PX), at least one of the plurality of sub-pixels (SP) is a top-emission sub-pixel (SPT), and at least one of the plurality of sub-pixels (SP) is a bottom-emission sub-pixel (SPB), the top-emission sub-pixel (SPT) and the bottom-emission sub-pixel (SPB) emit light toward a same side of the display panel.

### CROSS-REFERENCE TO RELATED APPLICATION

The patent application claims the priority of the Chinese patent application No. 202311285063.1 filed on Sep. 28, 2023, the entire disclosure of which is incorporated herein by reference as part of the present application.

### TECHNICAL FIELD

Embodiments of the present disclosure relate to a display panel and a display device.

### BACKGROUND

In the display field, organic light-emitting diode (OLED) display panels have the characteristics of self-luminescence, high contrast, low energy consumption, wide viewing angle, fast response speed, can be used for flexible panels, wide operating temperature range, and simple manufacturing, and the organic light-emitting diode (OLED) display panels have broad development prospects.

### SUMMARY

Embodiments of the present disclosure provide a display panel and a display device.

Embodiments of the present disclosure provide a display panel, including: a plurality of pixels, each of the plurality of pixels includes a plurality of sub-pixels, in a same pixel, at least one of the plurality of sub-pixels is a top-emission sub-pixel, and at least one of the plurality of sub-pixels is a bottom-emission sub-pixel, the top-emission sub-pixel and the bottom-emission sub-pixel emit light toward a same side of the display panel.

For example, a light-emitting area of at least one top-emission sub-pixel is smaller than a light-emitting area of at least one bottom-emission sub-pixel.

For example, the pixel includes an even number of sub-pixels, in the same pixel, the top-emission sub-pixel and the bottom-emission sub-pixel are arranged in a mirror-image manner.

For example, the plurality of sub-pixels are four sub-pixels, two sub-pixels of the four sub-pixels are top-emission sub-pixels, the other two sub-pixels of the four sub-pixels are bottom-emission sub-pixels.

For example, the bottom-emission sub-pixels are a sub-pixel emitting blue light and a sub-pixel emitting white light, and the top-emission sub-pixels are a sub-pixel emitting red light and a sub-pixel emitting green light.

For example, the pixel includes an odd number of sub-pixels, in the same pixel, a light-emitting area of at least one sub-pixel is greater than or equal to a sum of light-emitting areas of the other two sub-pixels.

For example, the plurality of sub-pixels are three sub-pixels, two of the three sub-pixels are top-emission sub-pixels, and the other sub-pixel among the three sub-pixels is a bottom-emission sub-pixel.

For example, the bottom-emission sub-pixel is a sub-pixel emitting blue light, and the top-emission sub-pixels are a sub-pixel emitting red light and a sub-pixel emitting green light.

For example, a light-emitting area of the sub-pixel emitting blue light is larger than a light-emitting area of the sub-pixel emitting red light, and is larger than a light-emitting area of the sub-pixel emitting green light.

For example, the display panel has a base substrate, and the top-emission sub-pixel and the bottom-emission sub-pixel are arranged at opposite sides of the base substrate, respectively.

For example, the display panel includes a first side and a second side which are opposite to each other, the first side is a light-emitting side, the top-emission sub-pixel is located at the first side, the bottom-emission sub-pixel is located at the second side, and the display panel has a transparent region at the first side, and an orthographic projection of the transparent region on the base substrate is overlapped with an orthographic projection of a light-emitting region of the bottom-emission sub-pixel on the base substrate.

For example, an area of the orthographic projection of the transparent region on the base substrate is greater than or equal to an area of the orthographic projection of the light-emitting region of the bottom-emission sub-pixel on the base substrate.

For example, each of the plurality of sub-pixels includes a pixel circuit and a light-emitting element, and an orthographic projection of the pixel circuit of the top-emission sub-pixel on the base substrate is overlapped with an orthographic projection of the pixel circuit of the bottom-emission sub-pixel on the base substrate.

For example, an orthographic projection of the light-emitting element of the top-emission sub-pixel on the base substrate is overlapped with the orthographic projection of the pixel circuit of the bottom-emission sub-pixel on the base substrate.

For example, the pixel circuit of the top-emission sub-pixel is closer to the base substrate than the light-emitting element of the top-emission sub-pixel, and the pixel circuit of the bottom-emission sub-pixel is closer to the base substrate than the light-emitting element of the bottom-emission sub-pixel.

For example, the pixel circuit includes a first transistor, a second transistor, a third transistor, and a storage capacitor, the display panel further includes a gate line, the gate line is connected with a gate electrode of the second transistor and a gate electrode of the third transistor, and the first transistor is located at a side of the storage capacitor facing away from the gate line.

For example, the second transistor and the third transistor are located at a side of the storage capacitor close to the gate line.

For example, the display panel further includes a data line, a sensing line and a first power line, the data line is connected with the second transistor, the first power line is connected with the first transistor, the sensing line is connected with the third transistor, and the data line, the sensing line, and the first power line are located in a same layer.

For example, the display panel further includes an auxiliary electrode, the light-emitting element includes a first electrode connected with the pixel circuit, a light-emitting functional layer located at a side of the first electrode facing away from the base substrate, and a second electrode located at a side of the light-emitting functional layer facing away from the first electrode, the second electrode is connected with the auxiliary electrode, and the auxiliary electrode, the data line, the sensing line, and the first power line are located in a same layer.

For example, the display panel further includes a light shielding layer, the light shielding layer is located at a side of the pixel circuit close to the base substrate, a first electrode of the first transistor is connected with a first electrode of the light-emitting element, and the light shielding layer is connected with the first electrode of the first transistor.

For example, the display panel further includes a first pixel defining layer, the first pixel defining layer is located at the first side of the display panel, the first pixel defining layer has a first opening and a second opening, the first opening is configured to define a light-emitting region of the top-emission sub-pixel, and an orthographic projection of the second opening on the base substrate is overlapped with an orthographic projection of the transparent region on the base substrate.

For example, an area of the first opening is smaller than an area of the second opening.

For example, the display panel further includes a second pixel defining layer, the second pixel defining layer is located at the second side of the display panel, the second pixel defining layer has a third opening, the third opening is configured to define a light-emitting region of the bottom-emission sub-pixel, and an area of the third opening is smaller than or equal to an area of the second opening.

Embodiments of the present disclosure further provide a display device, including any one of the display panels as described above.

### BRIEF DESCRIPTION OF DRAWINGS

In order to more clearly illustrate the technical solution of the embodiments of the present disclosure, the drawings of the embodiments will be briefly described in the following. Apparently, the described drawings in the following are only related to some embodiments of the present disclosure without any limitation to the present disclosure.

FIG. 1 is a schematic diagram of a display panel provided by an embodiment of the present disclosure.

FIG. 2 is a schematic diagram of another display panel provided by an embodiment of the present disclosure.

FIG. 3 is a cross-sectional view of a display panel provided by an embodiment of the present disclosure.

FIG. 4 is a cross-sectional view of another display panel provided by an embodiment of the present disclosure.

FIG. 5 is a cross-sectional view of another display panel provided by an embodiment of the present disclosure.

FIG. 6 is a cross-sectional view of another display panel provided by an embodiment of the present disclosure.

FIG. 7A is a schematic diagram of a 3T1C pixel circuit in a display panel provided by an embodiment of the present disclosure.

FIG. 7B is a signal timing diagram of the pixel circuit shown in FIG. 7A during a display process.

FIG. 7C and FIG. 7D are signal timing diagrams of the pixel circuit shown in FIG. 7A during a detection process.

FIG. 8 to FIG. 15 are plan views of a single film layer in a display panel provided by an embodiment of the present disclosure.

FIG. 16 to FIG. 23 are plan views of stacked layers of several film layers in a display panel provided by an embodiment of the present disclosure.

### DETAILED DESCRIPTION

In order to make objectives, technical details, and advantages of the embodiments of the present disclosure more clearly, the technical solutions of the embodiments will be described in a clearly and fully understandable way in connection with the drawings related to the embodiments of the present disclosure. Apparently, the described embodiments are just a part but not all of the embodiments of the present disclosure. Based on the described embodiments herein, those skilled in the art can obtain other embodiment(s), without any inventive work, which should be within the scope of the present disclosure.

Unless otherwise defined, all the technical and scientific terms used herein have the same meanings as commonly understood by one of ordinary skill in the art to which the present disclosure belongs. The terms “first,” “second,” etc., which are used in the present disclosure, are not intended to indicate any sequence, amount or importance, but distinguish various components. The terms “comprise,” “comprising,” “include,” “including,” etc., are intended to specify that the elements or the objects stated before these terms encompass the elements or the objects and equivalents thereof listed after these terms, but do not preclude the other elements or objects. The phrases “connect”, “connected”, etc., are not intended to define a physical connection or mechanical connection, but may include an electrical connection, directly or indirectly.

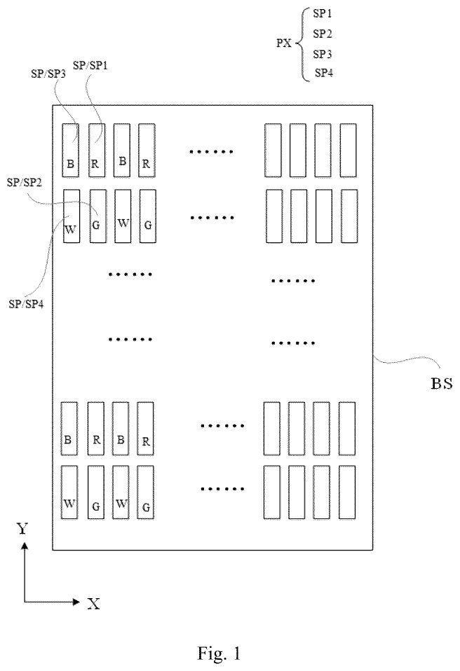

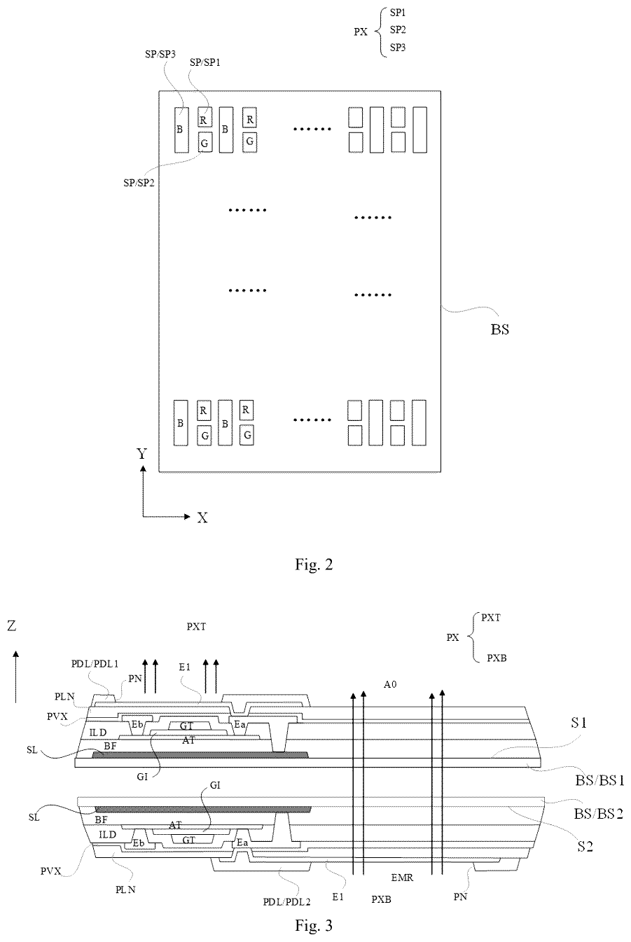

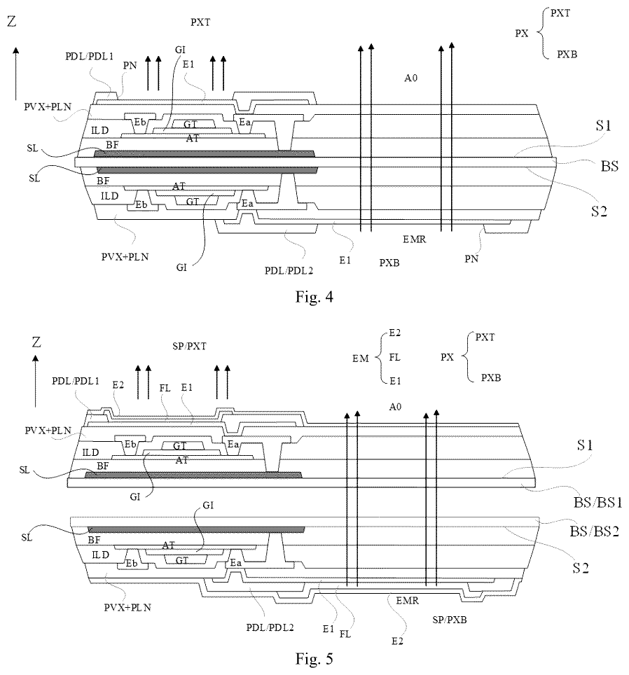

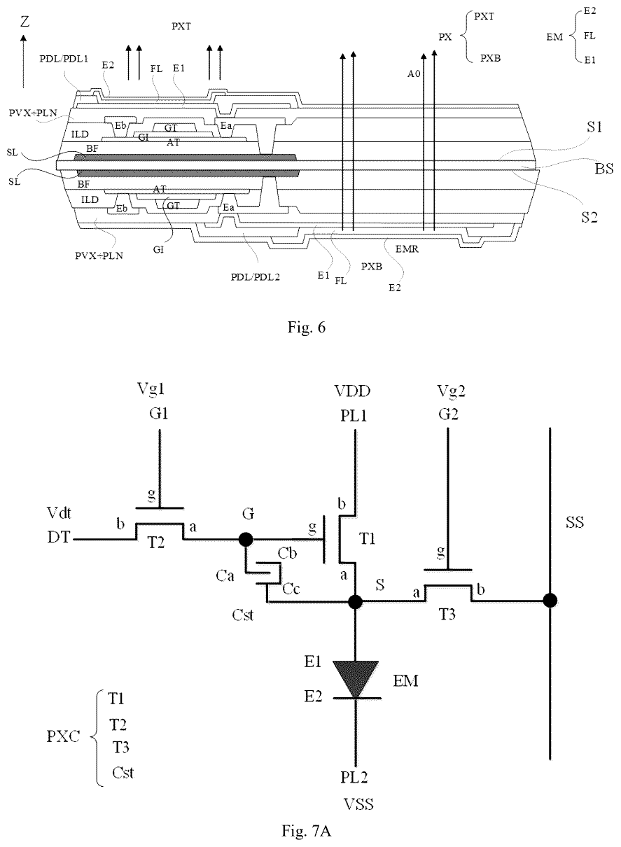

FIG. 1 is a schematic diagram of a display panel provided by an embodiment of the present disclosure. FIG. 2 is a schematic diagram of another display panel provided by an embodiment of the present disclosure. FIG. 3 is a cross-sectional view of a display panel provided by an embodiment of the present disclosure. FIG. 4 is a cross-sectional view of another display panel provided by an embodiment of the present disclosure. FIG. 5 is a cross-sectional view of another display panel provided by an embodiment of the present disclosure. FIG. 6 is a cross-sectional view of another display panel provided by an embodiment of the present disclosure.

As illustrated in FIG. 1 and FIG. 2, an embodiment of the present disclosure provides a display panel, the display panel includes a plurality of pixels PX, and each of the plurality of pixels PX includes a plurality of sub-pixels SP.

As illustrated in FIG. 1, each of the plurality of pixels PX includes four sub-pixels SP, that is, each of the plurality of the pixels PX includes a sub-pixel SP1, a sub-pixel SP2, a sub-pixel SP3, and a sub-pixel SP4. As illustrated in FIG. 1, the sub-pixel SP1 and the sub-pixel SP2 are arranged along a direction Y, the sub-pixel SP3 and the sub-pixel SP4 are arranged along the direction Y, the sub-pixel SP1 and the sub-pixel SP3 are arranged along a direction X, and the sub-pixel SP2 and the sub-pixel SP4 are arranged along the direction X. That is, four sub-pixels SP are arranged in two rows and two columns. For example, in the display panel shown in FIG. 1, in two adjacent columns of sub-pixels, in one column of sub-pixels, several sub-pixels SP1 and several sub-pixels SP2 are alternately arranged along the direction Y, in another column of sub-pixels, several sub-pixels SP3 and several sub-pixels SP4 are alternately arranged along the direction Y. For example, in the display panel shown in FIG. 1, in two adjacent rows of sub-pixels, in one row of sub-pixels, several sub-pixels SP1 and several sub-pixels SP3 are alternately arranged along the direction X, in another row of sub-pixels, several sub-pixels SP2 and several sub-pixels SP4 are alternately arranged along the direction X.

FIG. 1 is described by taking the case that the sub-pixel SP1 is a red sub-pixel, the sub-pixel SP2 is a green sub-pixel, the sub-pixel SP3 is a blue sub-pixel, and the sub-pixel SP4 is a white sub-pixel as an example. However, light-emitting colors of the sub-pixels SP are not limited to the above descriptions, and other colors of light may be emitted, the sub-pixels SP may not be arranged in two rows and two columns, but may be arranged in other ways. The embodiment of the present disclosure does not specifically limit the light-emitting colors of the sub-pixel SP1, the sub-pixel SP2, the sub-pixel SP3, and the sub-pixel SP4, which can be determined according to needs.

As illustrated in FIG. 2, each of the plurality of pixels PX includes three sub-pixels SP, that is, each of the plurality of pixels PX includes a sub-pixel SP1, a sub-pixel SP2, and a sub-pixel SP3. As illustrated in FIG. 2, the sub-pixel SP1 and the sub-pixel SP2 are arranged along the direction Y and are both located at the same side of the sub-pixel SP3. As illustrated in FIG. 2, lines connecting centers of the sub-pixel SP1, the sub-pixel SP2, and the sub-pixel SP3 form a triangle. For example, the triangle may be an acute triangle to facilitate an arrangement of the sub-pixels. As illustrated in FIG. 2, in two adjacent columns of sub-pixels, several sub-pixels SP1 and several sub-pixels SP2 in one column of sub-pixels are arranged alternately, and the other column of the sub-pixels are sub-pixels of the same color.

FIG. 2 is described by taking the case that the sub-pixel SP1 is a red sub-pixel, the sub-pixel SP2 is a green sub-pixel, and the sub-pixel SP3 is a blue sub-pixel as an example. However, the light-emitting colors of the sub-pixels SP are not limited to the above descriptions, and other colors of light may be emitted, the sub-pixels SP can also be not arranged in the manner illustrated in FIG. 2, but arranged in other manners. The embodiment of the present disclosure does not specifically limit the light-emitting colors of the sub-pixel SP1, the sub-pixel SP2, and the sub-pixel SP3, which can be determined according to requirements.

FIG. 1 and FIG. 2 show a base substrate BS. A plurality of pixels PX are located on the base substrate BS.

As illustrated in FIG. 3 to FIG. 6, in the same pixel PX, at least one sub-pixel SP among the plurality of sub-pixels SP is a top-emission sub-pixel SPT, and at least one sub-pixel SP among the plurality of sub-pixels SP is a bottom-emission sub-pixel SPB, and the top-emission sub-pixel SPT and the bottom-emission sub-pixel SPB emit light toward the same side of the display panel.

The display panel provided by the embodiment of the present disclosure is configured such that, in the same pixel PX, at least one sub-pixel SP among the plurality of sub-pixels SP is set as a top-emission sub-pixel SPT, and at least one sub-pixel SP among the plurality of sub-pixels SP is set as a bottom-emission sub-pixel SPB, that is, a plurality of sub-pixels of the same pixel PX are designed in layers, so that openings of the sub-pixels are not limited by a minimum distance of the pixel definition layer in a case of the same layer design (a plurality of sub-pixels in the same pixel are all top-emission sub-pixels, or all bottom-emission sub-pixels), which is beneficial for achieving the maximization of the openings of the sub-pixels, in particular, the openings of the sub-pixels are maximized at high resolution. Generally speaking, a minimum distance of the pixel defining layer is above 10 micrometers.

In the display panel provided by the embodiment of the present disclosure, different sub-pixels of a pixel are designed in layers, and two parts are basically designed as mirror images, namely the top-emission sub-pixel and the bottom-emission sub-pixel, a light-emitting region of the bottom-emission sub-pixel after left-right inversion can correspond to the transparent region at a side where the top-emission sub-pixel is located, the pixel circuits of the two parts are stacked or the two parts are made on two base substrates respectively, which can maximize the sub-pixel opening under high resolution.

FIG. 3 to FIG. 6 illustrate a top-emission sub-pixel SPT and a bottom-emission sub-pixel SPB. For example, a light-emitting area of at least one top-emission sub-pixel SPT is smaller than a light-emitting area of at least one bottom-emission sub-pixel SPB. By setting the area of the bottom-emission sub-pixel SPB to be larger, it is avoided that the brightness of the bottom-emission sub-pixel SPB is greatly reduced, which is beneficial for improving display quality.

For example, as illustrated in FIG. 1, each of the plurality of pixels PX includes an even number of sub-pixels SP, in the same pixel PX, the top-emission sub-pixel SPT and the bottom-emission sub-pixel SPB are arranged in a mirror-image manner. The number of top-emission sub-pixels SPT and the number of bottom-emission sub-pixels SPB are the same, and their structures are mirror images. That is, half of the even number sub-pixels SP are the top-emission sub-pixels SPT, and the other half of the even number sub-pixels SP are the bottom-emission sub-pixels SPB. The mirror-image arrangement is conducive to space utilization and improving the display quality.

For example, as illustrated in FIG. 1, the plurality of sub-pixels SP are four sub-pixels SP, two sub-pixels SP among the four sub-pixels SP are top-emission sub-pixels SPT, and the other two sub-pixels SP among the four sub-pixels SP are bottom-emission sub-pixels SPB. For example, as illustrated in FIG. 1, the sub-pixel SP1 and the sub-pixel SP2 are top-emission sub-pixels SPT, and the sub-pixel SP3 and the sub-pixel SP4 are bottom-emission sub-pixels SPB.

For example, the bottom-emission sub-pixels SPB are a sub-pixel SP emitting blue light (sub-pixel SP3, B) and a sub-pixel SP emitting white light (sub-pixel SP4, W), and the top-emission sub-pixels SPT are a sub-pixel SP emitting red light (sub-pixel SP1, R) and a sub-pixel SP emitting green light (sub-pixel SP2, G). A manner in which each of the plurality of pixels PX includes four sub-pixels of RGBW can reduce the power consumption of the display panel. According to different life spans of the light-emitting elements of the sub-pixels of different colors, the top-emission sub-pixels may be RG, while the bottom-emission sub-pixels may be BW.

For example, as illustrated in FIG. 2, the pixel PX includes an odd number of sub-pixels SP, in order to facilitate an arrangement of the sub-pixels, in the same pixel PX, a light-emitting area of at least one sub-pixel SP is greater than or equal to a sum of light-emitting areas of the other two sub-pixels SP. As illustrated in FIG. 2, a light-emitting area of the sub-pixel SP3 is larger than a sum of a light-emitting area of the sub-pixel SP1 and a light-emitting area of the sub-pixel SP2. Of course, in other embodiments, the light-emitting area of the sub-pixel SP3 may be equal to the sum of the light-emitting area of the sub-pixel SP1 and the light-emitting area of the sub-pixel SP2.

For example, as illustrated in FIG. 2, the plurality of sub-pixels SP are three sub-pixels SP, two sub-pixels SP of the three sub-pixels SP are top-emission sub-pixels SPT, and the other sub-pixel SP among the three sub-pixels SP is a bottom-emission sub-pixel SPB.

For example, as illustrated in FIG. 2, the bottom-emission sub-pixel SPB is a sub-pixel SP emitting blue light (sub-pixel SP3), and the top-emission sub-pixels SPT are a sub-pixel SP emitting red light (sub-pixel SP1) and a sub-pixel SP emitting green light (sub-pixel SP2).

As illustrated in FIG. 2, the top-emission sub-pixels SPT are the sub-pixels SP1 and the sub-pixels SP2 (RG), and the bottom-emission sub-pixels SPB are the sub-pixels SP3 (B). According to different life spans of the light-emitting elements of the sub-pixels of different colors, the top-emission sub-pixels may be RG, while the bottom-emission sub-pixel may be B.

For example, as illustrated in FIG. 2, the light-emitting area of the sub-pixel SP emitting blue light (sub-pixel SP3) is larger than the light-emitting area of the sub-pixel SP emitting red light (sub-pixel SP1), and is larger than the light-emitting area of the sub-pixel SP emitting green light (sub-pixel SP2).

A sub-pixel with a larger light-emitting area may be used as a bottom-emission sub-pixel SPB.

As illustrated in FIG. 5 and FIG. 6, in the display panel, the sub-pixel SP has a light-emitting element EM, the light-emitting element EM includes a first electrode E1, a light-emitting functional layer FL located at a side of the first electrode E1 facing away from the base substrate BS, and a second electrode E2 located at a side of the light-emitting functional layer FL facing away from the first electrode E1. The first electrode E1 is connected with a pixel circuit.

For example, as illustrated in FIG. 1 to FIG. 6, the display panel includes a base substrate BS, the top-emission sub-pixel SPT and the bottom-emission sub-pixel SPB are respectively arranged at opposite sides of the base substrate BS. FIG. 4 and FIG. 6 show the base substrate BS. FIG. 3 and FIG. 5 show that the base substrate BS includes a base substrate BS1 and a base substrate BS2. In the case where the base substrate BS includes the base substrate BS1 and the base substrate BS2, the components on the base substrate BS1 and the components on the base substrate BS2 can be manufactured separately first, and then the base substrate BS1 and the base substrate BS2 can be bonded together.

For example, as illustrated in FIG. 3 to FIG. 6, the base substrate BS of the display panel includes a first side S1 and a second side S2 opposite to each other, the first side S1 is a light-emitting side, the top-emission sub-pixels SPT are located at the first side S1, and the bottom-emission sub-pixels SPB are located at the second side S2, the first side S1 of the display panel has a transparent region A0, an orthographic projection of the transparent region A0 on the base substrate BS is overlapped with an orthographic projection of a light-emitting region EMR of the bottom-emission sub-pixel SPB on the base substrate BS.

In the embodiment of the present disclosure, each of the top-emission sub-pixels SPT emits light from a side where its second electrode E2 is located to a side facing away from the base substrate, and each of the bottom-emission sub-pixels SPB emits light from a side where its first electrode E1 is located to a side facing the base substrate.

In the embodiment of the present disclosure, a light-emitting region EMR of a sub-pixel SP refers to an actual light-emitting region of the sub-pixel, and may correspond to an opening of a pixel defining layer.

In the embodiment of the present disclosure, the transparent region A0 refers to a region without a light blocking member. The light shielding member includes, for example, a metal member. An insulating layer may be arranged in the transparent region A0, or a transparent or a semi-transparent metal layer may be disposed. As illustrated in FIG. 5 and FIG. 6, an insulating layer and a second electrode E2 may be arranged in the transparent region A0.

For example, in order to increase brightness of a bottom-emission sub-pixel SPB, an area of the orthographic projection of the transparent region A0 on the base substrate BS is greater than or equal to an area of the orthographic projection of the light-emitting region EMR of the bottom-emission sub-pixel SPB on the base substrate BS.

FIG. 3 and FIG. 4 omit the light-emitting functional layer FL and the second electrode E2. FIG. 5 and FIG. 6 show the light-emitting functional layer FL and the second electrode E2.

As illustrated in FIG. 3 to FIG. 6, the display panel further includes a light shielding layer SL, a buffer layer BF located at a side of the light shielding layer SL facing away from the base substrate BS, an active layer AT located at a side of the buffer layer BF facing away from the base substrate BS, an insulating layer GI located at a side of the active layer AT facing away from the base substrate BS, a gate electrode GT located at a side of the insulating layer GI facing away from the base substrate BS, an insulating layer ILD located at a side of the gate electrode GT facing away from the base substrate BS, a first electrode Ea and a second electrode Eb of a transistor located at a side of the insulating layer ILD facing away from the base substrate BS, and a passivation layer PVX and a planarization layer PLN located at a side of the first electrode Ea and the second electrode Eb facing away from the base substrate BS. As illustrated in FIG. 3 to FIG. 6, the first electrode E1 of the light-emitting element EM is connected with the first electrode Ea of the transistor through a via hole penetrating the passivation layer PVX and the planarization layer PLN. As illustrated in FIG. 3 to FIG. 6, the first electrode Ea of the transistor is connected with an active layer AT through a via hole penetrating the insulating layer ILD, and a second electrode Eb of the transistor is connected with the active layer AT through a via hole penetrating the insulating layer ILD. As illustrated in FIG. 3 to FIG. 6, the first electrode Ea of the transistor is also connected with the light shielding layer SL through a via hole penetrating the insulating layer ILD and the buffer layer BF to prevent the light shielding layer SL from floating.

As illustrated in FIG. 3 to FIG. 6, the pixel defining layer PDL has an opening PN, and the opening PN is configured to expose a part of the first electrode E1 to form a light-emitting region of a sub-pixel or a light-emitting element. FIG. 3 to FIG. 6 illustrate a pixel defining layer PDL1 and a pixel defining layer PDL2. The pixel defining layer PDL1 is located at the first side S1, and the pixel defining layer PDL2 is located at the second side S2.

FIG. 3 shows the passivation layer PVX and the planarization layer PLN. The passivation layer PVX is closer to the base substrate BS than the planarization layer PLN. FIG. 4 to FIG. 6 briefly illustrate the passivation layer PVX and the planarization layer PLN, which can be referred to as illustrated in FIG. 3.

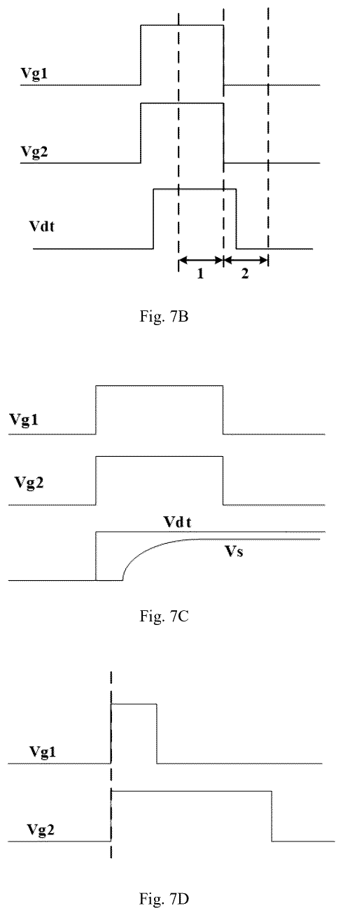

FIG. 7A is a schematic diagram of a 3T1C pixel circuit in a display panel provided by an embodiment of the present disclosure. The pixel circuit of the display panel provided by the embodiment of the present disclosure is not limited to the 3T1C pixel circuit, in the present embodiment, the structure of the display panel is described by taking a 3T1C pixel circuit as an example. As required, the pixel circuit may further include a compensation circuit, a reset circuit, which are not limited in the embodiments of the present disclosure.

Referring to FIG. 7A, the pixel circuit includes a first transistor T1, a second transistor T2, a third transistor T3, and a storage capacitor Cst. The first transistor Tl is a driving transistor, and the second transistor T2 is a data writing transistor. A first electrode of the second transistor T2 is electrically connected with a first electrode plate Ca of the storage capacitor Cst and a gate electrode of the first transistor T1, respectively, a second electrode of the second transistor T2 is connected with a data line DT, and is configured to receive a data signal Vdt, a gate electrode of the second transistor T2 is connected with a gate line G1, and the gate line G1 is configured to provide a first control signal Vg1, the second transistor T2 is configured to write the data signal Vdt into the gate electrode of the first transistor T1 and the storage capacitor Cst in response to the first control signal Vg1; a first electrode of the first transistor T1 is electrically connected with a second electrode plate Cb of the storage capacitor Cst, and is configured to be electrically connected with the first electrode E1 of a light-emitting element, and a second electrode of the first transistor T1 is connected with a first power line PL1, and is configured to receive a first power voltage (for example, a high power voltage VDD), the first power line PL1 is configured to provide a first power voltage. The first transistor T1 is configured to control a current for driving the light-emitting element under a control of a voltage on a gate electrode of the first transistor T1; a first electrode of the third transistor T3 is electrically connected with the first electrode of the first transistor T1 and the second electrode plate Cb of the storage capacitor Cst, respectively, a second electrode of the third transistor T3 is configured to be connected with a sensing line SS to be connected with an external detection circuit, a gate electrode of the third transistor T3 is connected with a gate line G2, and the gate line G2 is configured to provide a second control signal Vg2, the third transistor T3 is configured to detect the electrical characteristics of a sub-pixel to which it belongs in response to the second control signal Vg2 to achieve external compensation; the electrical characteristics include, for example, a threshold voltage and/or carrier mobility of the first transistor T1, or a threshold voltage and a driving current of the light-emitting element. The external detection circuit is, for example, a conventional circuit including a digital-to-analog converter (DAC) and an analog-to-digital converter (ADC), which will not be described in detail in the embodiments of the present disclosure. FIG. 7A shows the gate electrodes g, the first electrodes a, and the second electrodes b of the transistors.

As illustrated in FIG. 7A, the first electrode of the second transistor T2, the first electrode plate Ca of the storage capacitor Cst, and the gate electrode of the first transistor T1 are all connected with a node G.

As illustrated in FIG. 7A, the second electrode plate Cb, the third electrode plate Cc, the first electrode of the first transistor T1, the first electrode of the third transistor T3, and the first electrode E1 of the light-emitting element are all connected with a node S.

As illustrated in FIG. 7A, the second electrode E2 of the light-emitting element EM is connected with a second power line PL2 to receive a second power voltage (for example, a low power voltage VSS). The second power line PL2 is configured to provide a second power voltage.

For example, the storage capacitor Cst shown in FIG. 7A further includes a third electrode plate Cc, the third electrode plate Cc is located at a side of the first electrode plate Ca facing away from the second electrode plate Cb and is electrically connected with the second electrode plate Cb to form a parallel capacitor structure, thereby increasing a capacitance value of the storage capacitor Cst. For example, in a direction perpendicular to the base substrate BS, the third electrode plate Cc, the second electrode plate Cb, and the first electrode plate Ca are all overlapped with each other.

The transistors used in the embodiments of the present disclosure may be thin film transistors, field effect transistors or other switching components with the same characteristics, in the embodiments of the present disclosure, thin film transistors are used as examples for description. Source electrodes and drain electrodes of the transistors used herein may be symmetrical in structure, so there may be no difference in structure between the source electrodes and the drain electrodes. In the embodiments of the present disclosure, in order to distinguish two electrodes of a transistor except a gate electrode, one of the electrodes is directly described as a first electrode, and the other electrode is directly described as a second electrode. In addition, the transistors can be divided into N-type transistors and P-type transistors according to the characteristics of the transistors. In a case where a transistor is a P-type transistor, a turn-on voltage is a low level voltage (for example, OV, −5V, −10V or other suitable voltages), and a turn-off voltage is a high level voltage (for example, 5V, 10V or other suitable voltage); in a case where a transistor is an N-type transistor, a turn-on voltage is a high level voltage (for example, 5V, 10V or other suitable voltage), and a turn-off voltage is a low level voltage (for example, 0 V, −5 V, −10 V, or other suitable voltage). It should be noted that, in the following descriptions, the transistors in FIG. 7A are N-type transistors, which is taken as an example, but it does not constitute a limitation on the present disclosure.

A working principle of the pixel circuit illustrated in FIG. 7A is described below in conjunction with signal timing diagrams illustrated in FIG. 7B to FIG. 7D, in which FIG. 7B shows a signal timing diagram of the pixel circuit during a display process, and FIG. 7C and FIG. 7D show signal timing diagrams of the pixel circuit during a detection process.

For example, as illustrated in FIG. 7B, a display process of each frame of image includes a data writing and resetting phase 1 and a light-emitting phase 2. FIG. 7B shows the timing waveforms of various signals in each phase. The working process of the 3T1C pixel circuit includes: in the data writing and resetting phase 1, the first control signal Vg1 and the second control signal Vg2 are both turn-on signals, the second transistor T2 and the third transistor T3 are turned on, the data signal Vdt is transmitted to the gate electrode of the first transistor T1 via the second transistor T2, an analog-to-digital converter writes a reset signal to the first electrode E1 of the light-emitting element (for example, an anode electrode of the OLED) through the sensing line SS and the third transistor T3, the first transistor T1 is turned on and generates a driving current to charge the first electrode E1 of the light-emitting element EM to an operating voltage; in the light-emitting phase 2, the first control signal Vg1 and the second control signal Vg2 are both turn-off signals, due to bootstrap effect of the storage capacitor Cst, the voltages at two ends of the storage capacitor Cst remain unchanged, the first transistor T1 operates in a saturation state and the current remains unchanged, and the light-emitting element is driven to emit light.

For example, FIG. 7C shows a signal timing diagram of the pixel circuit when detecting the threshold voltage. The working process of the 3T1C pixel circuit includes the following phases: the first control signal Vg1 and the second control signal Vg2 are both turn-on signals, the second transistor T2 and the third transistor T3 are turned on, the data signal Vdt is transmitted to the gate electrode of the first transistor T1 via the second transistor T2; the analog-to-digital converter writes a reset signal to the first electrode El (node S) of the light-emitting element EM through the sensing line SS and the third transistor T3, the first transistor T1 is turned on and charges the node S until the first transistor T1 is turned off, the digital-to-analog converter samples the voltage on the sensing line SS to obtain the threshold voltage of the first transistor T1. This process can be performed, for example, in a case that the display device is turned off. Vs in FIG. 7C represents a voltage at the node S.

For example, FIG. 7D shows a signal timing diagram of the pixel circuit when detecting carrier mobility. The working process of the 3T1C pixel circuit includes the following phases: in a first phase, the first control signal Vg1 and the second control signal Vg2 are both turn-on signals, the second transistor T2 and the third transistor T3 are turned on, and the data signal Vdt is transmitted to the gate electrode of the first transistor T1 via the second transistor T2; the analog-to-digital converter writes a reset signal to the first electrode E1 (node S) of the light-emitting element EM through the sensing line SS and the third transistor T3; in the second phase, the first control signal Vg1 is a turn-off signal, and the second control signal Vg2 is a turn-on signal, the second transistor T2 is turned off, and the third transistor T3 is turned on, so as to float the sensing line SS; due to the bootstrap effect of the storage capacitor Cst, the voltages at two ends of the storage capacitor Cst remain unchanged, the first transistor T1 works in a saturated state and the current remains unchanged and drives the light-emitting element to emit light, then the digital-to-analog converter samples the voltage on the sensing line SS, and can calculate the carrier mobility of the first transistor T1 in combination with the magnitude and duration of the light-emitting current. For example, this process can be performed during a blanking phase between display phases.

Through the above detection, the electrical characteristics of the first transistor T1 can be obtained and a corresponding compensation algorithm can be implemented.

For example, the display panel may further include data driving circuits and scan driving circuits (not shown). The data driving circuit is configured to send data signals according to needs (such as image signals input to the display device), such as the above-mentioned data signal Vdt; the pixel circuit of each of the plurality of sub-pixels is further configured to receive the data signal and apply the data signal to the gate electrode of the first transistor. The scan driving circuit is configured to output various scan signals, for example, including the first control signal Vg1 and the second control signal Vg2 mentioned above. For example, the scan driving circuit is an integrated circuit chip (IC) or a gate driver circuit (GOA) directly manufactured on a display panel.

For example, the display panel further includes a control circuit. For example, the control circuit is configured to control a data driving circuit to apply a data signal, and control a gate driving circuit to apply a scan signal. An example of the control circuit is a timing control circuit (T-con). The control circuit can be in various forms, for example, including a processor and a memory. The memory includes executable codes, and the processor runs the executable codes to execute the above detection method.

For example, the processor may be a central processing unit (CPU) or other form of processing device having data processing capability and/or instruction execution capability, such as a microprocessor, and a programmable logic controller (PLC).

For example, the memory may include one or more computer program products, which may include various forms of computer-readable storage media, such as volatile memory and/or non-volatile memory. Volatile memory may include, for example, random access memory (RAM) and/or cache memory (cache). The non-volatile memory may include, for example, a read-only memory (ROM), a hard disk, and a flash memory. One or more computer program instructions may be stored on a computer-readable storage medium, and the processor may execute program instructions to achieve desired functions. Various application programs and various data, such as electrical characteristic parameters obtained in the above-mentioned detection method, can also be stored in the computer-readable storage medium.

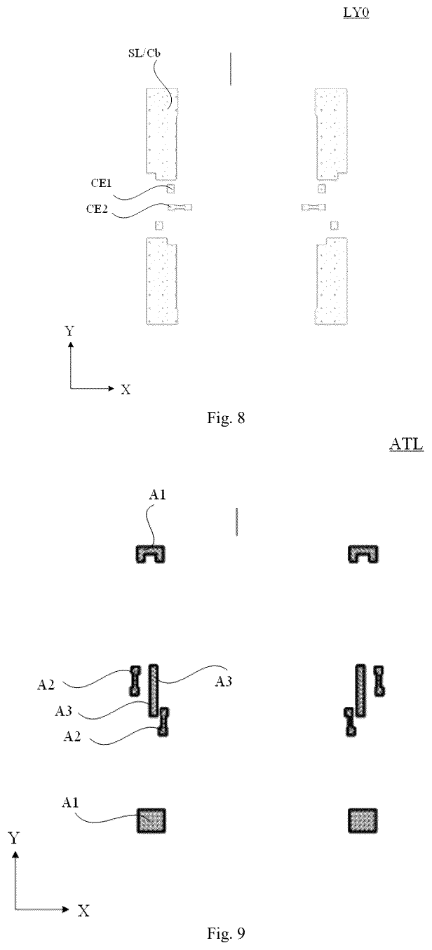

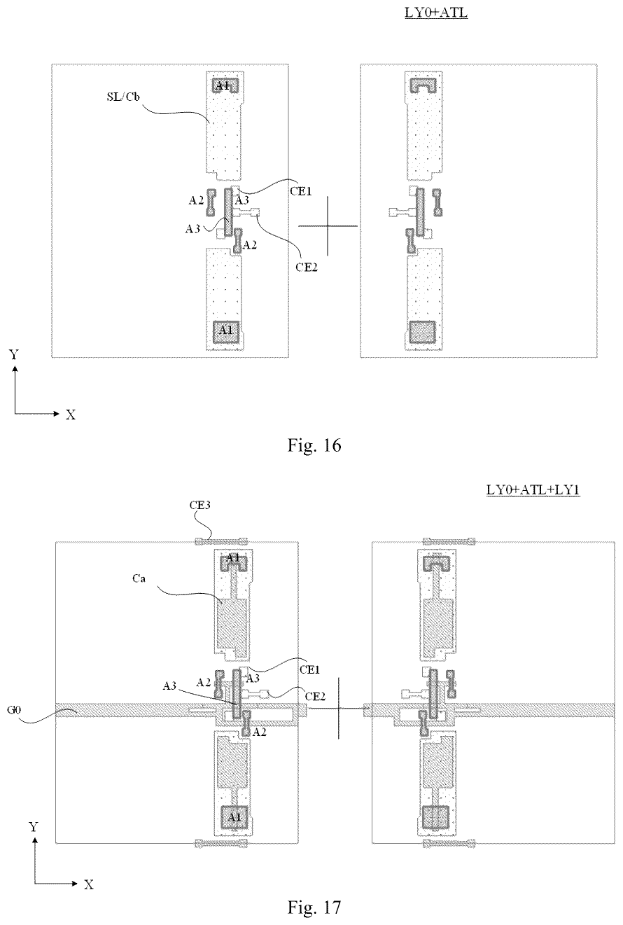

FIG. 8 to FIG. 15 are plan views of a single film layer in a display panel provided by an embodiment of the present disclosure. FIG. 16 to FIG. 23 are plan views of stacked layers of several film layers in a display panel provided by an embodiment of the present disclosure.

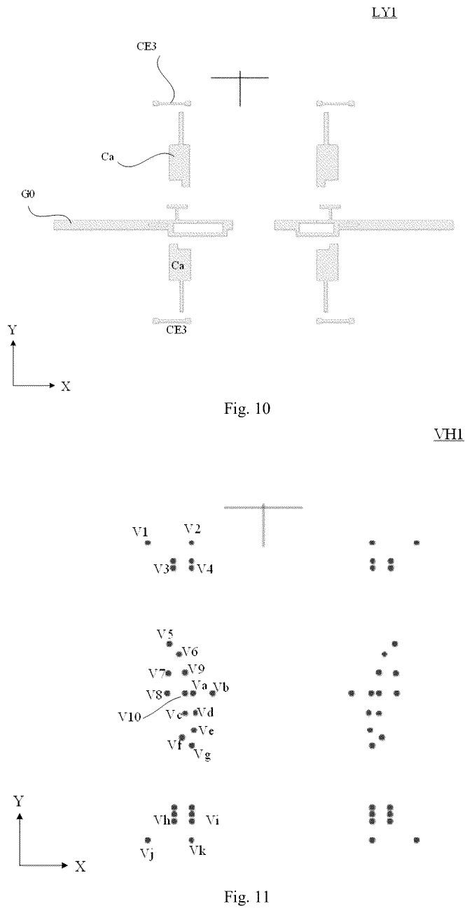

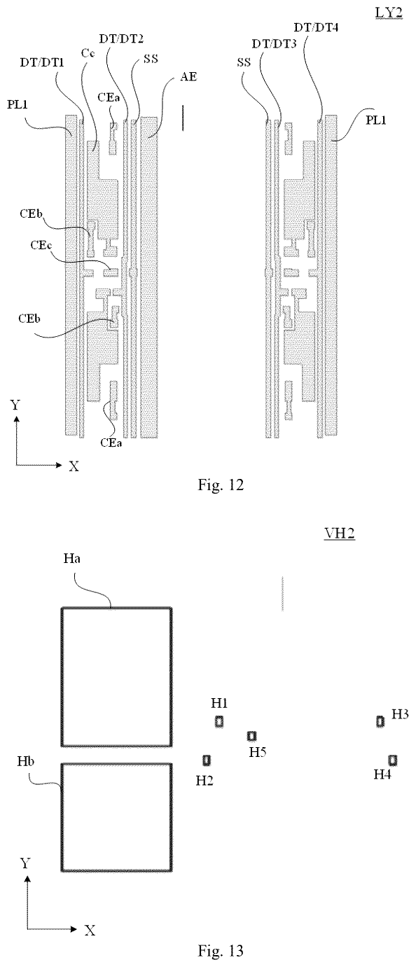

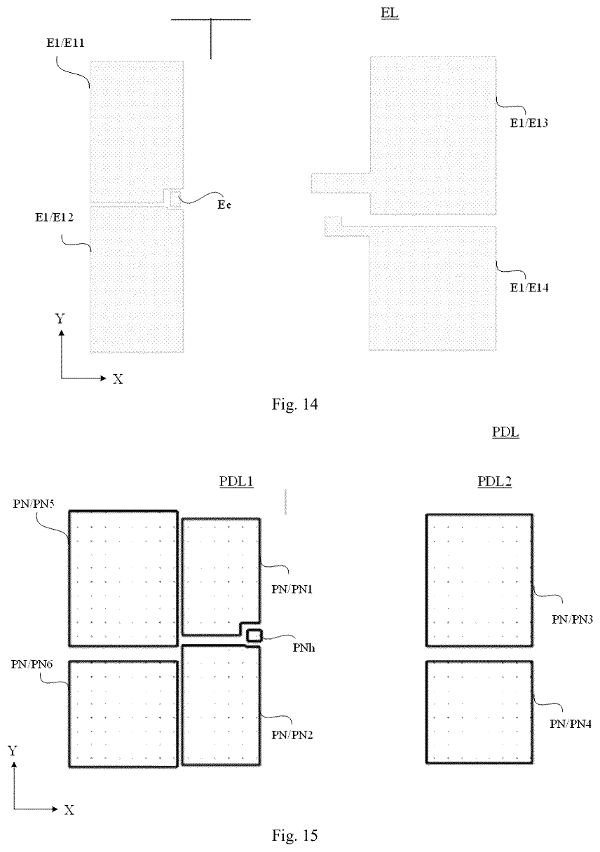

FIG. 8 is a plan view of a light shielding pattern LY0 in a display panel provided by an embodiment of the present disclosure. FIG. 9 is a plan view of an active pattern ATL in a display panel provided by an embodiment of the present disclosure. FIG. 10 is a plan view of a first conductive pattern LY1 in a display panel provided by an embodiment of the present disclosure. FIG. 11 is a plan view of a via hole pattern VH1 in a display panel provided by an embodiment of the present disclosure. FIG. 12 is a plan view of a second conductive pattern LY2 in a display panel provided by an embodiment of the present disclosure. FIG. 13 is a plan view of a via hole pattern VH2 in a display panel provided by an embodiment of the present disclosure. FIG. 14 is a plan view of an electrode pattern EL in a display panel provided by an embodiment of the present disclosure. FIG. 15 is a plan view of a pixel defining layer PDL in a display panel provided by an embodiment of the present disclosure.

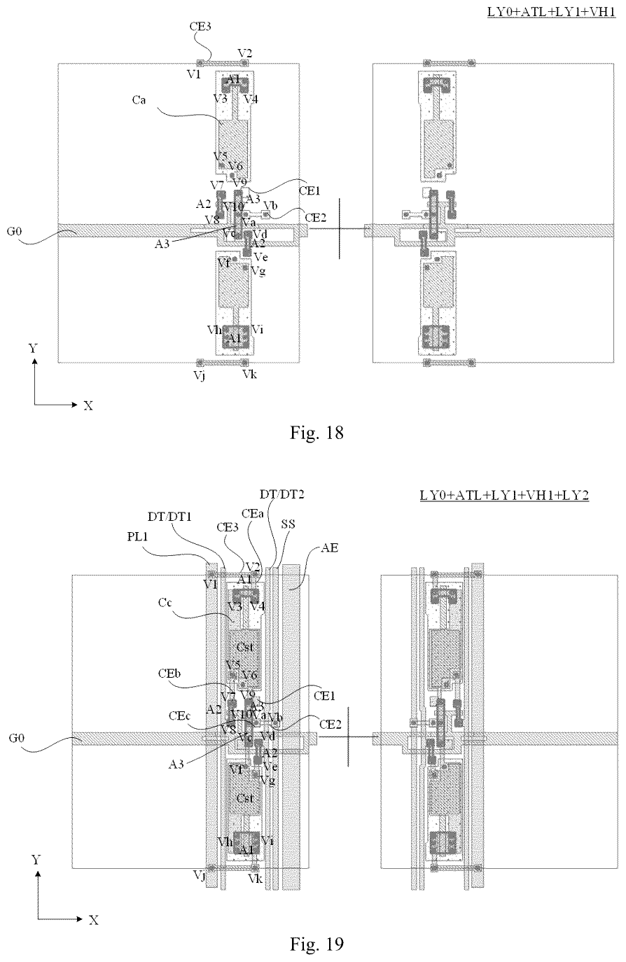

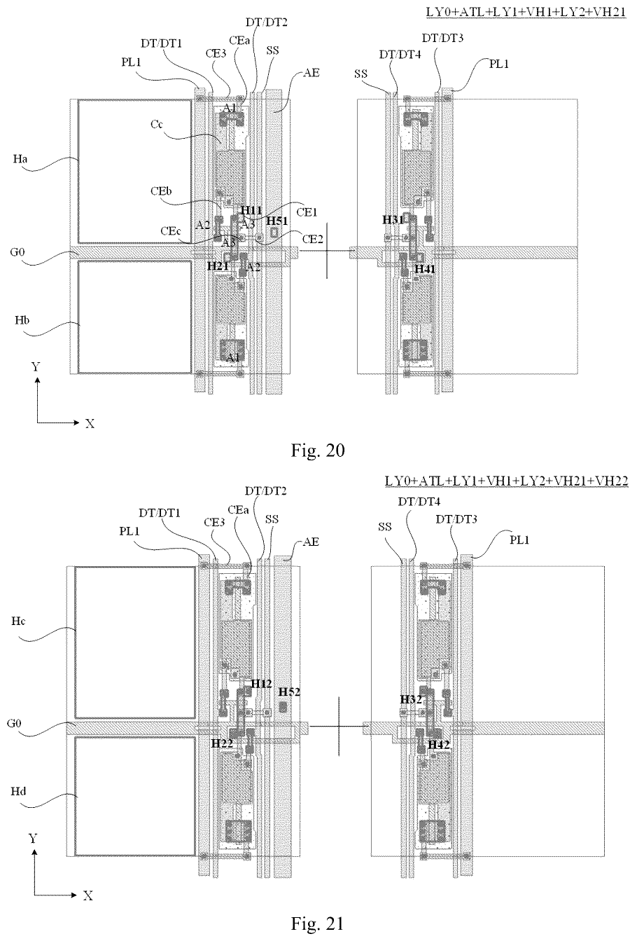

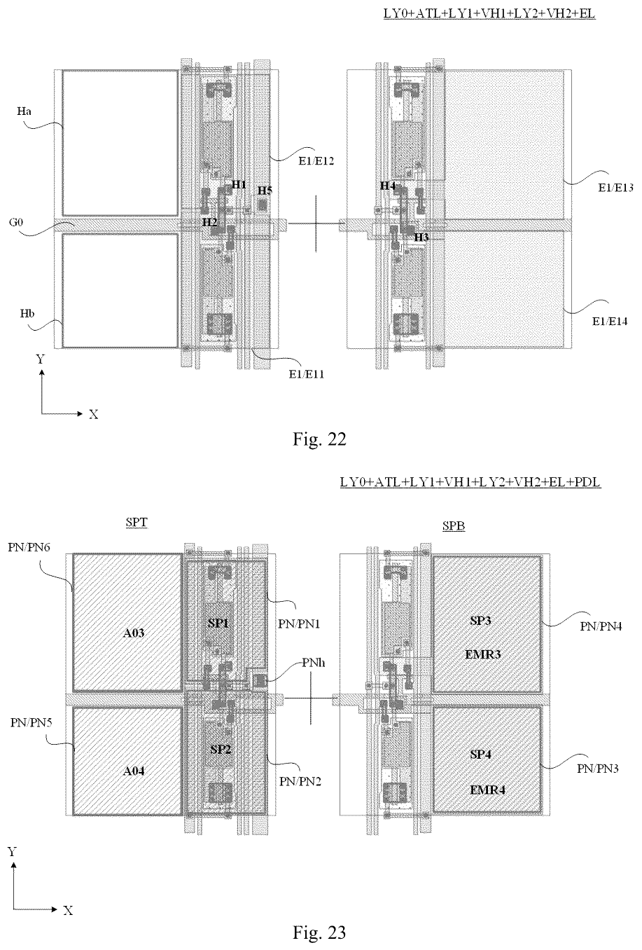

FIG. 16 is a plan view of a light shielding pattern LY0 and an active pattern ATL in a display panel provided by an embodiment of the present disclosure. FIG. 17 is a plan view of a light shielding pattern LY0, an active pattern ATL, and a first conductive pattern LY1 in a display panel provided by an embodiment of the present disclosure. FIG. 18 is a plan view of stacked layers of a light shielding pattern LY0, an active pattern ATL, a first conductive pattern LY1, and a via hole pattern VH1 in a display panel provided by an embodiment of the present disclosure. FIG. 19 is a plan view of stacked layers of a light shielding pattern LY0, an active pattern ATL, a first conductive pattern LY1, a via hole pattern VH1, and a second conductive pattern LY2 in a display panel provided by an embodiment of the present disclosure. FIG. 20 is a plan view of stacked layers of a light shielding pattern LY0, an active pattern ATL, a first conductive pattern LY1, a via hole pattern VH1, a second conductive pattern LY2, and a via hole pattern VH21 in a display panel provided by an embodiment of the present disclosure. FIG. 21 is a plan view of stacked layers of a light shielding pattern LY0, an active pattern ATL, a first conductive pattern LY1, a hole via pattern VH1, a second conductive pattern LY2, a via hole pattern VH21, and a via hole pattern VH22 in a display panel provided by an embodiment of the present disclosure. FIG. 22 is a plan view of stacked layers of a light shielding pattern LY0, an active pattern ATL, a first conductive pattern LY1, a via hole pattern VH1, a second conductive pattern LY2, a via hole pattern VH2, and an electrode pattern EL in a display panel provided by an embodiment of the present disclosure. FIG. 23 is a plan view of stacked layers of a light shielding pattern LY0, an active pattern ATL, a first conductive pattern LY1, a via hole pattern VH1, a second conductive pattern LY2, a via hole pattern VH2, an electrode pattern EL, and a pixel defining layer PDL in a display panel provided by an embodiment of the present disclosure.

As illustrated in FIG. 8, the light shielding pattern LY0 includes a light shielding layer SL, a connection electrode CE1, and a connection electrode CE2. As illustrated in FIG. 8, the light shielding layer SL also serves as a second electrode plate Cb. The connection electrode CE1 serves as a base pad or a blocking pad to prevent the via hole subsequently formed at the position from affecting the base substrate.

As illustrated in FIG. 9, the active pattern ATL includes an active layer A1, an active layer A2, and an active layer A3. In each of the active layer A1, the active layer A2, and the active layer A3, the middle part is a semiconductor layer, and the parts on two sides are conductor parts, which can be used as a first electrode and a second electrode of a transistor, respectively. As illustrated in FIG. 9, active layers A3 of transistors in two adjacent sub-pixels in the direction Y (column direction) are connected with each other, and form an integral structure.

As illustrated in FIG. 10, the first conductive pattern LY1 includes a first electrode plate Ca, a gate line G0, and a connection electrode CE3. The gate line G1 and the gate line G2 in FIG. 7A are of an integral structure, and are both a gate line G0. A part of the gate line G0 is a gate electrode of the second transistor T2, and a part of the gate line G0 is a gate electrode of the third transistor. That is, the gate line G0, the gate electrode of the second transistor T2, and the gate electrode of the third transistor are of an integral structure.

As illustrated in FIG. 11, the via hole pattern VH1 includes via holes V1 to V10 and via holes Va to Vk. The via hole pattern VH1 includes a via hole penetrating the buffer layer BF and the insulating layer ILD and a via hole penetrating the insulating layer ILD.

As illustrated in FIG. 12, the second conductive pattern LY2 includes a first power line PL1, a data line DT, a third electrode plate Cc, a sensing line SS, an auxiliary electrode AE, a connection electrode CEa, a connection electrode CEb, and a connection electrode CEc. As illustrated in FIG. 12, the auxiliary electrode AE is arranged in a left part of the figure, while the auxiliary electrode AE is not arranged in a right part of the figure. That is, the auxiliary electrode AE is arranged at a side where a top-emission sub-pixel is located, but the auxiliary electrode AE is not arranged at a side where a bottom-emission sub-pixel is located. Of course, in other embodiments, the auxiliary electrode AE may also be arranged at a side where the bottom-emission sub-pixel is located.

As illustrated in FIG. 12, the data line DT extends along the direction Y, and a plurality of data lines DT are arranged along the direction X. The plurality of data lines DT include a data line DT1, a data line DT2, a data line DT3, and a data line DT4. As illustrated in FIG. 12, the data line DT1, the data line DT2, the data line DT4, and the data line DT3 are sequentially arranged along the direction X.

As illustrated in FIG. 13, the via hole pattern VH2 includes an opening Ha, an opening Hb, and a via hole H1 to a via hole H5.

As illustrated in FIG. 14, the electrode pattern EL includes a plurality of first electrodes E1. FIG. 14 shows four first electrodes E1. FIG. 14 shows a first electrode E11, a first electrode E12, a first electrode E13, and a first electrode E14.

As illustrated in FIG. 15, the pixel defining layer PDL includes a pixel defining layer PDL1 and a pixel defining layer PDL2.

As illustrated in FIG. 15, the pixel defining layer PDL1 has an opening PN1, an opening PN2, an opening PN5, an opening PN6, and a via hole PNh.

As illustrated in FIG. 16, the pixel defining layer PDL2 has an opening PN3 and an opening PN4.

FIG. 8 to FIG. 23 show a marking line located in the middle of the drawings, which is a vertical line, a T-shaped line or a cross line. The marking line can be seen as a dividing line. A left side of the marking line is a top-emission sub-pixel, and a right side of the marking line is a bottom-emission sub-pixel. For ease of description, plan views of a top-emission sub-pixel and a bottom-emission sub-pixel are placed in the same drawing.

Referring to FIG. 13, FIG. 21, and FIG. 22, the via hole pattern VH2 includes a via hole pattern VH21 (referring to FIG. 20) and a via hole pattern VH22 (referring to FIG. 21). The via hole pattern VH21 is a via hole penetrating the passivation layer PVX, and the via hole pattern VH22 is a via hole penetrating the planarization layer PLN. As illustrated in FIG. 20, the via hole pattern VH21 includes an opening Ha, an opening Hb, a via hole H11, a via hole H21, a via hole H31, a via hole H41, and a via hole H51. As illustrated in FIG. 21, the via hole pattern VH22 includes an opening Hc, an opening Hd, a via hole H12, a via hole H22, a via hole H32, a via hole H42, and a via hole H52. Referring to FIG. 13, FIG. 21, and FIG. 22, the via hole H11 and the via hole H12 constitute the via hole H1, the via hole H21 and the via hole H22 constitute the via hole H2, the via hole H31 and the via hole H32 constitute the via hole H3, the via hole H41 and the via hole H42 constitute the via hole H4, and the via hole H51 and the via hole H52 constitute the via hole H5.

As illustrated in FIG. 14 and FIG. 23, the second electrode E2 is connected with the connection electrode CEe through the via hole PNh. The connection electrode CEe is connected with the auxiliary electrode AE through the via hole H5 to reduce a resistance of the second electrode E2.

As illustrated in FIG. 14 and FIG. 22, the first electrode E11 is connected with the third electrode plate Cc (node S) through the via hole H1, the first electrode E12 is connected with the third electrode plate Cc (node S) through the via hole H2, the first electrode E13 is connected with the third electrode plate Cc (node S) through the via hole H3, and the first electrode E14 is connected with the third electrode plate Cc (node S) through the via hole H4. Each of the plurality of sub-pixels has its own pixel circuit PXC.

Referring to FIG. 7A, FIG. 8 to FIG. 12, FIG. 18, and FIG. 19, the first power line PL1 is connected with one end of the connection electrode CE3 through the via hole V1, and the other end of the connection electrode CE3 is connected with one end of the connection electrode CEa through the via hole V2. The other end of the connection electrode CEa is connected with the active layer A1 (the second electrode of the first transistor T1) through the via hole V4. The third electrode plate Cc is connected with the active layer A1 (the first electrode of the first transistor T1) and the second electrode plate Cb through the via hole V3, respectively. In an upper left sub-pixel of FIG. 19, a middle part of the active layer A1 is a semiconductor layer, a left side of the semiconductor layer of the active layer A1 is the first electrode of the first transistor T1, and a right side of the semiconductor layer of the active layer A1 is the second electrode of the first transistor T1.

Referring to FIG. 7A, FIG. 8 to FIG. 12, FIG. 18, and FIG. 19, one end of the connection electrode CEb is connected with the first electrode plate Ca through a via hole V5, and the other end of the connection electrode CEb is connected with the active layer A2 (a first electrode of the second transistor T2) through a via hole V7. The data line DT1 is connected with the active layer A2 (a second electrode of the second transistor T2) through a via hole V8. In an upper left sub-pixel of FIG. 19, a middle part of the active layer A2 is a semiconductor layer, an upper side of the semiconductor layer of the active layer A2 is a first electrode of the second transistor T2, and a lower side of the semiconductor layer of the active layer A2 is a second electrode of the second transistor T2.

Referring to FIG. 7A, FIG. 8 to FIG. 12, FIG. 18, and FIG. 19, the third electrode plate Cc is connected with the second electrode plate Cb through a via hole V6.

Referring to FIG. 7A, FIG. 8 to FIG. 12, FIG. 18, and FIG. 19, one end of the connection electrode CEc is connected with the active layer A3 (a second electrode of the third transistor T3) through the via hole V10, the other end of the connection electrode CEc is connected with one end of the connection electrode CE2 through the via hole Va, and the other end of the connection electrode CE2 is connected with the sensing line SS through the via hole Vb. The third electrode plate Cc is connected with the active layer A3 (a first electrode of the third transistor T3) through a via hole V9. In an upper left sub-pixel of FIG. 19, a middle portion of the active layer A3 is a semiconductor layer, an upper side of the semiconductor layer is the first electrode of the third transistor T3, and a lower side of the semiconductor layer is the second electrode of the third transistor T3.

The pixel circuit of the upper left sub-pixel is described above. The pixel circuit of the lower left sub-pixel is described below. As illustrated in FIG. 19, the first electrode of the third transistor T3 is connected with the third electrode plate Cc through a via hole Vc, the third electrode plate Cc is connected with the second electrode plate Cb through a via hole Vf, and the data line DT is connected with the second electrode of the second transistor T2 through a via hole Vd, the first electrode of the second transistor T2 is connected with one end of the connection electrode CEb through the via hole Ve, and the other end of the connection electrode CEb is connected with the first electrode plate Ca through a via hole Vg. The third electrode plate Cc is connected with the first electrode of the first transistor T1 and the second electrode plate Cb through the via hole Vh, respectively, the second electrode of the first transistor T1 is connected with one end of the connection electrode CEa through the via hole Vi, the other end of the connection electrode CEa is connected with one end of the connection electrode CE3 through the via hole Vk, and the other end of the connection electrode CE3 is connected with the first power line PL1 through a via hole Vj. In FIG. 19, the electrode Ea may be the third electrode plate Cc. The electrode Ea illustrated in FIG. 3 to FIG. 6 is respectively connected with the light shielding layer SL and the first electrode of the first transistor T1 through two via holes. In FIG. 19, the third electrode plate Cc is connected with the first electrode of the first transistor T1 and the second electrode plate Cb (light shielding layer SL) through the same via hole Vh.

As illustrated in FIG. 23, a double-layer structure may be formed by folding along the marking line or a line extending along the direction Y. That is, the opening PN4 is overlapped with the opening PN6 by folding, and the opening PN3 is overlapped with the opening PN5 by folding. The opening PN6 and the opening PN5 are the transparent regions A0 illustrated in FIG. 3 to FIG. 6. Thus, the display panel illustrated in FIG. 1 can be formed. Light emitted from the light-emitting region EMR3 of the sub-pixel SP3 illustrated in FIG. 23 is emitted from the transparent region A03. Light emitted from the light-emitting region EMR4 of the sub-pixel SP4 illustrated in FIG. 23 is emitted from the transparent region A04.

For example, as illustrated in FIG. 23, a light-emitting area of at least one top-emission sub-pixel SPT is smaller than a light-emitting area of at least one bottom-emission sub-pixel SPB.

For example, as illustrated in FIG. 15 and FIG. 23, in order to increase the brightness of the bottom-emission sub-pixel SPB, an area of an orthographic projection of the transparent region A0 on the base substrate BS is greater than or equal to an area of an orthographic projection of the light-emitting region EMR of the bottom-emission sub-pixel SPB on the base substrate BS.

For the bottom-emission sub-pixel SPB, the light-emitting region of the light-emitting element is not overlapped with the pixel circuit. As illustrated in FIG. 23, the pixel circuit of the bottom-emission sub-pixel SPB is on the left, and the light-emitting region of the light-emitting element is on the right.

For the top-emission sub-pixel SPT, the light-emitting region of the light-emitting element is overlapped with the pixel circuit.

For example, as illustrated in FIG. 3 to 6, FIG. 7A, and FIG. 23, the sub-pixel SP includes a pixel circuit PXC and a light-emitting element EM, an orthographic projection of the pixel circuit PXC of the top-emission sub-pixel SPT on the base substrate BS is overlapped with an orthographic projection of the pixel circuit PXC of the bottom-emission sub-pixel SPB on the base substrate BS. This configuration is beneficial for saving area and improving an aperture ratio of the sub-pixel.

For example, as illustrated in FIG. 3 to FIG. 6, FIG. 7A, and FIG. 23, an orthographic projection of the light-emitting element EM of the top-emission sub-pixel SPT on the base substrate BS is overlapped with an orthographic projection of the pixel circuit PXC of the bottom-emission sub-pixel SPB on the base substrate BS. This configuration is beneficial for saving area and improving an aperture ratio of the sub-pixel.

For example, as illustrated in FIG. 3 to FIG. 6, FIG. 7A, and FIG. 23, the pixel circuit PXC of the top-emission sub-pixel SPT is closer to the base substrate BS than the light-emitting element EM of the top-emission sub-pixel SPT, and the pixel circuit PXC of the bottom-emission sub-pixel SPB is closer to the base substrate BS than the light-emitting element EM of the bottom-emission sub-pixel SPB.

For example, as illustrated in FIG. 7A and FIG. 23, the pixel circuit PXC includes a first transistor T1, a second transistor T2, a third transistor T3, and a storage capacitor Cst.

For example, as illustrated in FIG. 7A, FIG. 10, FIG. 17, FIG. 19, and FIG. 23, the display panel further includes a gate line G0, the gate line G0 is connected with a gate electrode of the second transistor T2 and a gate electrode of the third transistor T3, and the first transistor T1 is located at a side of the storage capacitor Cst facing away from the gate line G0. This configuration is beneficial to the arrangement of the transistors and the storage capacitor Cst.

For example, as illustrated in FIG. 19, the second transistor T2 and the third transistor T3 are located at a side of the storage capacitor Cst close to the gate line G0. The positions of the active layers A1, A2, A3 in the figure are respectively the positions of the first transistor T1, the second transistor T2 and the third transistor T3.

For example, as illustrated in FIG. 19, the display panel further includes a data line DT, a sensing line SS and a first power line PL1, the data line DT is connected with the second transistor T2, and the first power line PL1 is connected with the first transistor T1, the sensing line SS is connected with the third transistor T3, and the data line DT, the sensing line SS, and the first power line PL1 are located in the same layer, and are all located in the second conductive pattern LY2.

For example, as illustrated in FIG. 3 to FIG. 6 and FIG. 19, the display panel further includes an auxiliary electrode AE, the light-emitting element EM includes a first electrode E1 connected to the pixel circuit PXC, a light-emitting functional layer FL located at a side of the first electrode E1 facing away from the substrate BS, and a second electrode E2 located at a side of the light-emitting functional layer FL facing away from the first electrode E1, the second electrode E2 is connected with the auxiliary electrode AE, the auxiliary electrode AE is located in the same layer as the data line DT, the sensing line SS, and the first power line PL1, and is located in the second conductive pattern LY2.

For example, as illustrated in FIG. 3 to FIG. 6, the display panel further includes a light shielding layer SL, the light shielding layer SL is located at a side of the pixel circuit PXC close to the base substrate BS, the first electrode of the first transistor T1 is connected with the first electrode E1 of the light-emitting element EM, and the light shielding layer SL is connected with the first electrode of the first transistor T1. The transistor illustrated in FIG. 3 to FIG. 6 can be regarded as the first transistor T1.

For example, as illustrated in FIG. 3 to FIG. 6 and FIG. 15, the display panel further includes a first pixel defining layer PDL1, the first pixel defining layer PDL1 is located at a first side S1 of the display panel, the first pixel defining layer PDL1 has an opening PN1 and an opening PN5, the opening PN1 is configured to define a light-emitting region of a top-emission sub-pixel. For example, an orthographic projection of the opening PN1 on the substrate BS is overlapped with an orthographic projection of the top-emission sub-pixel SPT on the substrate BS, and an orthographic projection of the opening PN5 on the base substrate BS is overlapped with an orthographic projection of the transparent region A0 on the base substrate BS.

For example, as illustrated in FIG. 15, an area of the opening PN1 is smaller than an area of the opening PN5. Thus, in some embodiments, an area of the top-emission sub-pixel is smaller than an area of the bottom-emission sub-pixel.

For example, as illustrated in FIG. 3 to FIG. 6 and FIG. 15, the display panel further includes a second pixel defining layer PDL2, and the second pixel defining layer PDL2 is located at a second side S2 of the display panel, the second pixel defining layer PDL2 has an opening PN3, the opening PN3 is configured to define a light-emitting region of a bottom-emission sub-pixel. For example, an orthographic projection of the opening PN3 on the substrate BS is overlapped with an orthographic projection of the bottom-emission sub-pixel SPB on the base substrate BS, and an area of the opening PN3 is smaller than or equal to an area of the opening PN5. This setting is beneficial for improving the aperture ratio of the sub-pixel.

The above descriptions are based on the structures of the upper half (the opening PN5, the opening PN1, and the opening PN3) in FIG. 15, similarly, the lower part (the opening PN6, the opening PN2, and the opening PN4) in FIG. 15 also has the structures described above, which will not be described in detail herein.

In the embodiment of the present disclosure, the light-emitting element may be an organic light-emitting diode (OLED), but is not limited to this.

In the embodiment of the present disclosure, the active layer of the transistor may be an oxide semiconductor, but is not limited to this.

In the embodiment of the present disclosure, the second electrode E2 of the top-emission sub-pixel may be a semi-transparent electrode, and the first electrode El of the top-emission sub-pixel may be a reflective electrode, but is not limited to this.

In the embodiment of the present disclosure, the second electrode E2 of the bottom-emission sub-pixel may be a reflective electrode, and the first electrode E1 of the top-emission sub-pixel may be a semi-transparent electrode, but is not limited to this.

For example, at least one of the light shielding pattern LY0, the first conductive pattern LY1, and the second conductive pattern LY may be made of a metal material.

For example, at least one of the buffer layer BF, the insulating layer GI, the insulating layer ILD, and the passivation layer PVX may be made of an inorganic insulating material. The inorganic insulating material includes at least one of silicon oxide, silicon nitride, and silicon oxynitride.

For example, at least one of the planarization layer PLN and the pixel defining layer PDL may be made of an organic insulating material. The organic insulating material includes resin, but is not limited to this.

For example, the base substrate BS may be a rigid substrate (such as, glass) or a flexible substrate (such as, polyimide).

Referring to FIG. 3 to FIG. 6 and FIG. 8 to FIG. 23, a method for manufacturing a backplate of a display panel includes the following steps.
(1) Forming a light shielding pattern LYO on a base substrate.

For example, depositing a metal film on a transparent substrate by sputtering process, and through photolithography, wet etching, and stripping the photoresist on the metal surface to obtain a light shielding pattern LYO, as illustrated in FIG. 8. For example, the base substrate is a glass substrate with a thickness of 50 μm to 1000 μm.
(2) Forming a buffer layer BF on the light shielding pattern LY0.

For example, depositing a buffer layer BF by a plasma enhanced chemical vapor deposition (PECVD) process, in which the buffer layer BF may be formed by overlapping one or more of SiNx, SiOx or SiOxNy, and a thickness of the buffer layer BF is from 150 nm to 500 nm.
(3) Forming an active pattern ATL on the buffer layer BF.

For example, depositing an oxide semiconductor as a pattern ATL on the buffer layer BF by using a sputtering process, as illustrated in FIG. 9. For example, the oxide semiconductor may be an amorphous oxide such as IGZO, ZnON, or ITZO.
(4) Forming an insulating layer GI on the active pattern ATL, and forming a first conductive pattern LY1 on the insulating layer GI, as illustrated in FIG. 10.

For example, depositing insulating films using a chemical vapor deposition (CVD) process; and depositing a gate metal layer on the insulating film by a sputtering process. For example, a thickness of the gate metal layer is from 200 nm to 1000 nm, for example, the metal includes at least one of Al, Mo, Cr, Cu, and Ti, defining the patterns of the gate lines, the connection electrodes and the electrode plates of the capacitor by photolithography and wet etching processes, while keeping the photoresist unstripped, continuing to use the photoresist on the gate metal layer as a mask to dry-etch the pattern of the insulating layer GI; using the gas such as NH₃, N₂ or H₂ to perform a converting-into-conductor treatment on the active pattern ATL exposed to the outside (a part not covered by the first conductive pattern LY1), to reduce the ohmic contact resistance between the active pattern ATL and the second conductive pattern LY2.
(5) Forming an insulating layer ILD on the first conductive pattern LY1, and forming a via hole pattern VH1, as illustrated in FIG. 11.

For example, insulating films are deposited by using PECVD processes, via holes connecting the second conductive pattern LY2 and the active pattern ATL are obtained by a dry etching process, and via holes connecting the second conductive pattern LY2 and the light shielding pattern LY0 are also obtained, to form the insulating layer ILD. For example, the insulating layer ILD is a single-layer or multi-layer film of SiNx or SiOx.
(6) Forming a second conductive pattern LY2 on the insulating layer ILD.

For example, a sputtering process is adopted to deposit a metal film, in which the metal may be Al, Mo, Cr, Cu, Ti, and so on, and a thickness of the metal is from 200 nm to 1000 nm, and a second conductive pattern LY2 is obtained by photolithography and wet etching processes, as illustrated in FIG. 12.
(7) Forming a passivation layer PVX on the second conductive pattern LY2.

For example, a CVD process is adopted to deposit a passivation layer PVX, in which the material of the passivation layer PVX may be SiO2.
(8) Forming a planarization layer PLN on the passivation layer PVX, and forming a via hole pattern VH2, as illustrated in FIG. 13.

For example, organic material is deposited by using a coating method (e.g., slit coating), pre-baking, exposure, and developing are performed to obtain the pattern in the pixel region, baking is performed at a certain temperature, for example, 230 degrees to remove water and organic solvents, and obtain a planarization layer with a thickness of 2.0 μm to 3.5 μm. Then exposing and etching are performed to form a via hole pattern VH2, in which the via holes in the via hole pattern VH2 are used to connect the electrode pattern EL with components in the second conductive pattern LY2.
(9) Forming an electrode pattern EL (a first electrode E1 of the light-emitting element) on the planarization layer PLN, as illustrated in FIG. 14.

For example, the first electrode E1 is deposited by a sputtering process, in which the material of the first electrode E1 may be Al, Mo, Cu, ITO, and so on, and a thickness of the first electrode E1 is from 100 nm to 600 nm, and the pattern of the first electrode E1 (electrode pattern EL) is obtained by photolithography and wet etching processes.
(10) Forming a pixel defining layer (PDL) on the electrode pattern EL.

For example, a pixel defining layer material is deposited by a coating method (such as slit coating), a pattern of a solidified pixel region is exposed through pre-baking, exposure and development, post-baking is performed at a certain temperature, for example, 230 degrees to remove water and organic solvents, to obtain the pixel defining layer PDL with a thickness of 1.8 μm to 2.0 μm.

After the above steps, the process for manufacturing the backplate is completed.

In some drawings of the embodiments of the present disclosure, a plan view shows the direction X and the direction Y, and a cross-sectional view shows a direction Z. Both the direction X and the direction Y are directions parallel with a main surface of the base substrate BS. The direction Z is a direction perpendicular to the main surface of the base substrate BS. For example, the direction X is intersected with the direction Y. The embodiments of the present disclosure are described by taking that case that the direction X and the direction Y are perpendicular to each other as an example. For example, the main surface of the base substrate BS is a surface of the base substrate BS used for manufacturing various elements. The upper surface and/or the lower surface of the base substrate BS in the cross-sectional view is the main surface of the base substrate BS. The direction Z is perpendicular to the direction X and perpendicular to the direction Y.

An embodiment of the present disclosure further provides a display device, and the display device includes any one of the display panels mentioned above.

For example, the display device may be an organic light-emitting diode display device. The display device may be any product or component with a display function, such as a television, a digital camera, a mobile phone, a watch, a tablet computer, a laptop computer, a navigator, etc., which includes an organic light-emitting diode display device.

The above are only specific embodiments of the present disclosure, but the protection scope of the present disclosure is not limited thereto. Any person skilled in the art can easily conceive of changes or substitutions within the technical scope disclosed in the present disclosure, and these changes or substitutions should be covered within the protection scope of the present disclosure. Therefore, the protection scope of the present disclosure should be subject to the protection scope of the claims.

1. A display panel, comprising: a plurality of pixels, wherein each of the plurality of pixels comprises a plurality of sub-pixels,
in a same pixel, at least one of the plurality of sub-pixels is a top-emission sub-pixel, and at least one of the plurality of sub-pixels is a bottom-emission sub-pixel, the top-emission sub-pixel and the bottom-emission sub-pixel emit light toward a same side of the display panel.

2. The display panel according to claim 1, wherein a light-emitting area of at least one top-emission sub-pixel is smaller than a light-emitting area of at least one bottom-emission sub-pixel.

3. The display panel according to claim 1, wherein the pixel comprises an even number of sub-pixels, in the same pixel, the top-emission sub-pixel and the bottom-emission sub-pixel are arranged in a mirror-image manner.

4. The display panel according to claim 1, wherein the plurality of sub-pixels are four sub-pixels, two sub-pixels of the four sub-pixels are top-emission sub-pixels, the other two sub-pixels of the four sub-pixels are bottom-emission sub-pixels.

5. The display panel according to claim 4, wherein the bottom-emission sub-pixels are a sub-pixel emitting blue light and a sub-pixel emitting white light, and the top-emission sub-pixels are a sub-pixel emitting red light and a sub-pixel emitting green light.

6. The display panel according to claim 1, wherein the pixel comprises an odd number of sub-pixels, in the same pixel, a light-emitting area of at least one sub-pixel is greater than or equal to a sum of light-emitting areas of the other two sub-pixels.

7. The display panel according to claim 1, wherein the plurality of sub-pixels are three sub-pixels, two of the three sub-pixels are top-emission sub-pixels, and the other sub-pixel among the three sub-pixels is a bottom-emission sub-pixel.

8. The display panel according to claim 7, wherein the bottom-emission sub-pixel is a sub-pixel emitting blue light, and the top-emission sub-pixels are a sub-pixel emitting red light and a sub-pixel emitting green light,
wherein a light-emitting area of the sub-pixel emitting blue light is larger than a light-emitting area of the sub-pixel emitting red light, and is larger than a light-emitting area of the sub-pixel emitting green light.

9. (canceled)

10. The display panel according to claim 1, wherein the display panel has a base substrate, and the top-emission sub-pixel and the bottom-emission sub-pixel are arranged at opposite sides of the base substrate, respectively.

11. The display panel according to the claim 10, wherein the display panel comprises a first side and a second side which are opposite to each other, the first side is a light-emitting side, the top-emission sub-pixel is located at the first side, the bottom-emission sub-pixel is located at the second side, and the display panel has a transparent region at the first side, and an orthographic projection of the transparent region on the base substrate is overlapped with an orthographic projection of a light-emitting region of the bottom-emission sub-pixel on the base substrate.

12. The display panel according to the claim 11, wherein an area of the orthographic projection of the transparent region on the base substrate is greater than or equal to an area of the orthographic projection of the light-emitting region of the bottom-emission sub-pixel on the base substrate.

13. The display panel according to claim 11, wherein each of the plurality of sub-pixels comprises a pixel circuit and a light-emitting element, and an orthographic projection of the pixel circuit of the top-emission sub-pixel on the base substrate is overlapped with an orthographic projection of the pixel circuit of the bottom-emission sub-pixel on the base substrate.

14. The display panel according to claim 13, wherein an orthographic projection of the light-emitting element of the top-emission sub-pixel on the base substrate is overlapped with the orthographic projection of the pixel circuit of the bottom-emission sub-pixel on the base substrate,
wherein the pixel circuit of the top-emission sub-pixel is closer to the base substrate than the light-emitting element of the top-emission sub-pixel, and the pixel circuit of the bottom-emission sub-pixel is closer to the base substrate than the light-emitting element of the bottom-emission sub-pixel.

15. (canceled)

16. The display panel according to claim 13, wherein the pixel circuit comprises a first transistor, a second transistor, a third transistor, and a storage capacitor,
the display panel further comprises a gate line, wherein the gate line is connected with a gate electrode of the second transistor and a gate electrode of the third transistor, and the first transistor is located at a side of the storage capacitor facing away from the gate line,
wherein the second transistor and the third transistor are located at a side of the storage capacitor close to the gate line.

17. (canceled)

18. The display panel according to claim 16, further comprising a data line, a sensing line and a first power line, wherein the data line is connected with the second transistor, the first power line is connected with the first transistor, the sensing line is connected with the third transistor, and the data line, the sensing line, and the first power line are located in a same layer.

19. The display panel according to claim 18, further comprising an auxiliary electrode, wherein the light-emitting element comprises a first electrode connected with the pixel circuit, a light-emitting functional layer located at a side of the first electrode facing away from the base substrate, and a second electrode located at a side of the light-emitting functional layer facing away from the first electrode, the second electrode is connected with the auxiliary electrode, and the auxiliary electrode, the data line, the sensing line, and the first power line are located in a same layer.

20. The display panel according to claim 16, further comprising a light shielding layer, wherein the light shielding layer is located at a side of the pixel circuit close to the base substrate, a first electrode of the first transistor is connected with a first electrode of the light-emitting element, and the light shielding layer is connected with the first electrode of the first transistor.

21. The display panel according to claim 11, further comprising a first pixel defining layer, wherein the first pixel defining layer is located at the first side of the display panel, the first pixel defining layer has a first opening and a second opening, the first opening is configured to define a light-emitting region of the top-emission sub-pixel, and an orthographic projection of the second opening on the base substrate is overlapped with an orthographic projection of the transparent region on the base substrate,
wherein an area of the first opening is smaller than an area of the second opening.

22. (canceled)

23. The display panel according to claim 21, further comprising a second pixel defining layer, wherein the second pixel defining layer is located at the second side of the display panel, the second pixel defining layer has a third opening, the third opening is configured to define a light-emitting region of the bottom-emission sub-pixel, and an area of the third opening is smaller than or equal to an area of the second opening.

24. A display device, comprising the display panel according to claim 1.
